(19) United States
(12) Patent Application Publication
(10) Pub. No.: US 2015/0212186 A1
(43) Pub. Date: Jul. 30, 2015

(54) METHOD OF CALIBRATING AND OPERATING TESTING SYSTEM

(71) Applicant: MPI CORPORATION, ZHUBEI (TW)

(72) Inventors: WEI-CHENG KU, ZHUBEI (TW); SHAO-WEI LU, ZHUBEI (TW); SHOU-JEN TSAI, ZHUBEI (TW); YU-TSE WANG, ZHUBEI (TW)

(73) Assignee: MPI CORPORATION, ZHUBEI (TW)

(21) Appl. No.: 14/558,450

(22) Filed: Dec. 2, 2014

(30) Foreign Application Priority Data
Dec. 31, 2013 (TW) 102149315

(51) Int. Cl. G01R 35/00; G01R 31/02

(52) U.S. Cl. CPC G01R 35/005; G01R 31/025

(57) ABSTRACT

A method of calibrating and operating a testing system is provided, wherein the testing system has a test machine, a conducting wire set, a calibration module, and a probe module. The method includes the following steps: electrically connect the test machine and the conducting wire set; electrically connect the conducting wire set and the calibration module; send out electrical signals from the test machine to the calibration module for doing at least one test among a short-circuit test, an open-circuit test, and an impedance test, and then calibrate the testing system by correspondingly performing compensation based on results of these tests; electrically disconnect the conducting wire set and the calibration module, and electrically connect the conducting wire set and the probe module; abut the probe module against a DUT; send out electrical signals from the test machine to the probe module to do electrical tests on the DUT.

### BACKGROUND OF THE INVENTION

1. Technical Field

The present invention relates generally to electrical tests, and more particularly to a method of calibrating and operating a testing system.

2. Description of Related Art

To ensure the quality of electronic products, manufacturers commonly use a testing system to check electrical connections between each precision electronic component in different stages of the manufacturing process.

In most cases, before doing electrical tests, the probes of a testing system may have to be calibrated by using a calibration plate, which does tests and provides information of compensation (i.e., returning to zero) for the probes. However, such compensation is applied on the whole circuit of the testing system at once, without knowing the actual condition of each component. Once a testing system is found malfunctioned, it has to take down and test every component in the testing system one by one just to find the problematic one. The process is time-consuming, and leads to poor efficiency of maintaining a testing system.

### BRIEF SUMMARY OF THE INVENTION

In view of the above, the primary objective of the present invention is to provide a method of calibrating and operating a testing system, which exactly knows the current condition of each component in the system, and if the testing system malfunctions, the method is able to effectively find out which component goes wrong.

The present invention provides a method of calibrating and operating a testing system, which includes a test machine a conducting wire set, a calibration module, and a probe module. The method includes the following steps: (a) electrically connect the test machine and the conducting wire set; (b) electrically connect the conducting wire set and the calibration module; (c) send out electrical signals from the test machine to the calibration module for doing at least one test among a short-circuit test, an open-circuit test, and an impedance test, and then calibrate the testing system by correspondingly performing compensation based on results of these tests; (d) electrically disconnect the conducting wire set and the calibration module; (e) electrically connect the conducting wire set and the probe module; and (f) abut the probe module against a DUT, and send out electrical signals from the test machine to the probe module to do electrical tests on the DUT.

With the aforementioned design of the method of operating the testing system, the current condition of each component of the testing system can be exactly known. Furthermore, when the testing system malfunctions, the component which goes wrong can be quickly found out.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a schematic diagram of a testing system suitable for a preferred embodiment of the present invention; and

FIG. 2 is a flow chart of the preferred embodiment of the present invention.

### DETAILED DESCRIPTION OF THE INVENTION

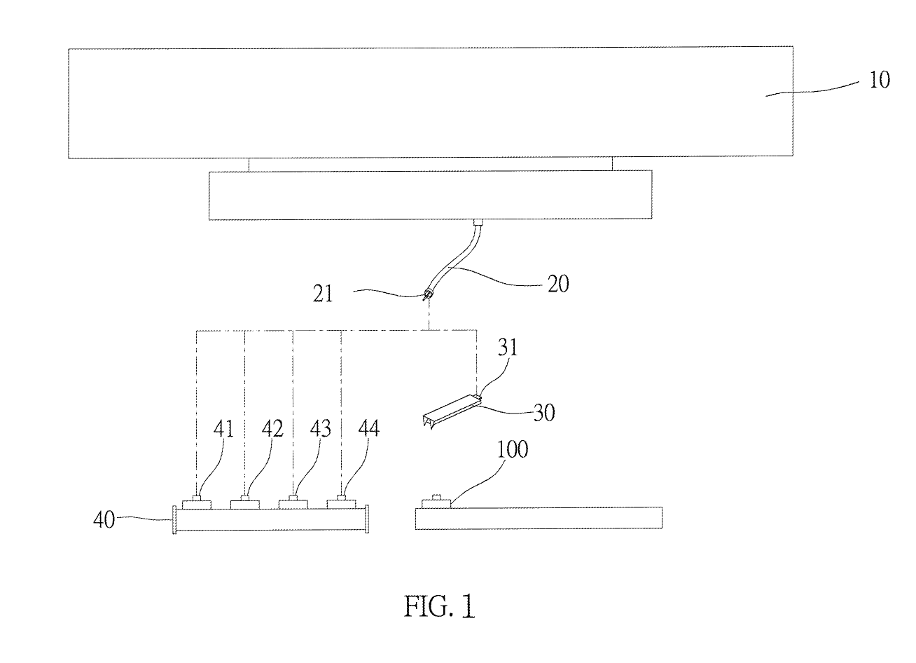

As shown in FIG. 1, a testing system includes a test machine 10, a conducting wire set 20, a probe module 30, and a calibration module 40, which are electrically connected in sequence. The conducting wire set 20 has a first connector 21 made of conductive materials at an end thereof. The probe module 30 has a second connector 31 which is made of conductive materials, and corresponds to the first connector 21. Similarly, the calibration module 40 has four second connectors 41-44, which are also made of conductive materials, and correspond to the first connector 21 as well, wherein the second connectors 41-44 are respectively electrically connected to components (not shown) corresponding to a short-circuit test, an impedance test of 50 ohm, an impedance test of 75 ohm, and an open-circuit test. In the preferred embodiment, the first connector 21 is a male connector, while the second connectors 31, 41-44 are female connectors. However, this is not a limitation of the present invention. Instead of the male and female connectors described herein, clips or other design which can repeatedly connect and disconnect two components can, of course, be used in other embodiments as well.

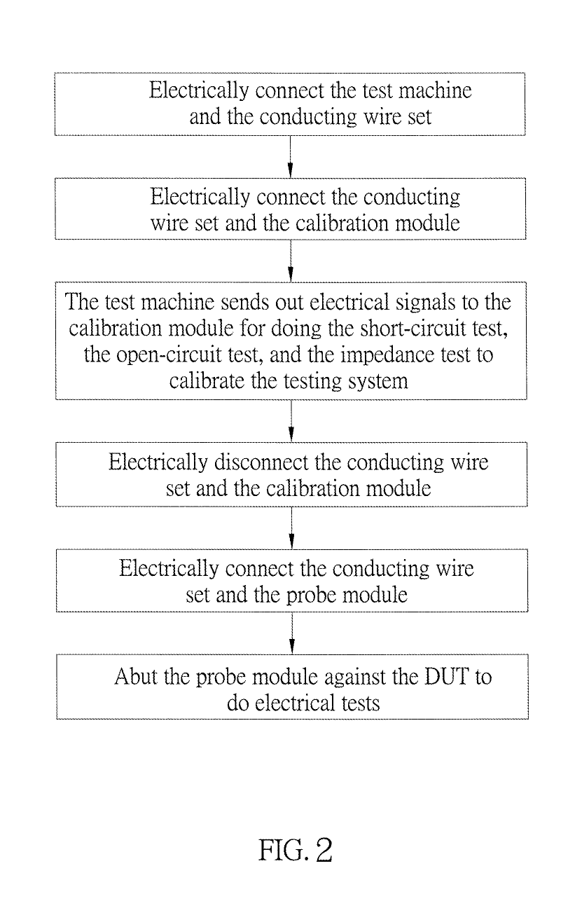

With the aforementioned design, when the testing system is operating, a method of calibrating and operating the testing system as shown in FIG. 2 can be performed to ensure the accuracy of test, wherein the method includes the following steps:

(a) Electrically connect the test machine 10 and the conducting wire set 20, so that test machine 10 can transmit electrical signals through the conducting wire set 20.

(b) Connect the first connector 21 of the conducting wire set 20 and one of the second connectors 41-44 of the calibration module 40. Whereby, the conducting wire set 20 and the calibration module 40 are electrically connected to each other.

(c) Control the test machine 10 to send out electrical signals to the calibration module 40 to do the short-circuit test, the open-circuit test, or the impedance test, depending on which second connector 41-44 is connected in step (b), and to calibrate the testing system by performing calibration on values (i.e., returning to zero, compensation on values, etc.) based on the result of the test.

(d) Disconnect the first connector 21 of the conducting wire set 20 and the second connector 41-44 connected in step (b) to electrically disconnect the conducting wire set 20 and the calibration module 40. It is worth mentioning that when the current step is finished, step (b) to step (d) can be repeatedly taken for a predetermined number of times to meet the requirement of test. In more details, when step (b) is taken again, the second connector 41-44 connected to the first connector 21 is different from the second connector 41-44 connected in the previously taken step (b), which leads to different test to be done in step (c). For example, if the second connector 41 related to the short-circuit test is connected when step (b) is taken for the first time, the second connector 42 related to the impedance test of 50 ohm could be selected to be connected when step (b) is taken for the second time. Similarly, when step (b) is taken for the third time, it could be the second connector 43 related to the impedance test of 75 ohm to be connected; as for the fourth time, the last second connector 44, which is related to the open-circuit test, could be connected to the first connector 21. In this way, the calibration can be more accurate due to there are more results obtained from the tests. In addition, the results of the impedance tests change in a way of ascending power with the aforementioned order of tests, wherein the impedance goes from low to high (i.e., 0 to 50, to 75, and then to infinity), which helps to increase the accuracy of the calibration. In practice, the impedance can, of course, go from high to low as well. In this way, after the calibration is done, it can be derived from the values during the calibration that whether the test machine 10 or the wirings thereof have any problem such as malfunction or aging.

(e) Connect the first connector 21 of the conducting wire set 20 and the second connector 31 of the probe module 30 to electrically connect the conducting wire set 20 and the probe module 30. After that, abut tips of the probe module 30 against a short-circuit pad, an open-circuit pad, and an impedance pad on a calibration plate (not shown) one at a time to do the short-circuit test, the open-circuit test, and the impedance test. Based on the results of these tests, the calibration on values (i.e., returning to zero, compensation on values, etc.) can be correspondingly performed. As a result, the testing system is calibrated again. In this way, the electrical test can be ensured to have high accuracy. Furthermore, it can be derived from the values during the calibration that whether the probe module has any problem such as malfunction or aging.

(f) Abut the probe module 30 against a DUT 100 after the calibration is completed. Whereby, test signals generated by the test machine 10 can be transmitted to the DUT 100 through the probe module 30, and then the test signals can be transmitted back to the test machine 10 through the probe module 30 and the conducting wire set 20 sequentially too, which forms a signal loop. As a result, the test machine 10 can do electrical tests on the DUT, for the electrical properties of the tested portion can be determined to be normal or abnormal according to the returned test signals.

With the aforementioned design, the current status of the test machine 10 and the probe module 30 of the testing system can be exactly known. Once the testing system malfunctions, it can be quickly and easily found out whether the test machine 10 or the probe module 30 malfunctions by electrically disconnecting the conducting wire set 20 and the probe module 30, and going through step (b) to step (d) all over again.

In practice, the initial settings and status of the probe module 30 usually, of course, comply with a standard, and therefore the process of calibration described in step (e) can be optionally skipped, and only performed when the electrical tests described in step (f) have been performed for a while, and the measured yields are uninterrupted low.

The embodiment described above is only a preferred embodiment of the present invention. All equivalent methods which employ the concepts disclosed in this specification and the appended claims should fall within the scope of the present invention.

What is claimed is:

1. A method of calibrating and operating a testing system, wherein the testing system includes a test machine a conducting wire set, a calibration module, and a probe module; the method comprising the steps of:
(a) electrically connecting the test machine and the conducting wire set;
(b) electrically connecting the conducting wire set and the calibration module;
(c) sending out electrical signals from the test machine to the calibration module for doing at least one test among a short-circuit test, an open-circuit test, and an impedance test, and then calibrate the testing system by correspondingly performing compensation based on results of these tests;
(d) electrically disconnecting the conducting wire set and the calibration module;
(e) electrically connecting the conducting wire set and the probe module; and
(f) abutting the probe module against a DUT, and send out electrical signals from the test machine to the probe module to do electrical tests on the DUT.

2. The method of claim 1, wherein the probe module is abutted against a calibration plate after step (e), and the test machine sends out electrical signals to the probe module to do at least one test among a short-circuit test, an open-circuit test, and an impedance test; the testing system is calibrated by correspondingly performing compensation on values based on result of the tests.

3. The method of claim 2, wherein the probe module is abutted against the calibration plate before step (f).

4. The method of claim 2, wherein the probe module is abutted against the calibration plate after step (f).

5. The method of claim 1, wherein the conducting wire set has a first connector at an end thereof, while the probe module has a corresponding second connector; in step (e), the conducting wire set and the probe module are electrically connected by connecting the first connector and the second connector.

6. The method of claim 1, wherein the conducting wire set has a first connector at an end thereof, while the calibration module has at least one corresponding second connector; in step (b), the conducting wire set and the calibration module are electrically connected by connecting the first connector and one of the at least one second connector; in step (d), the conducting wire set and the calibration module are electrically disconnected by disconnecting the first connector and the connected second connector.

7. The method of claim 6, wherein the at least one second connector includes at least three second connectors, which are electrically connected to components corresponding to the short-circuit test, the open-circuit test, and the impedance test respectively; in step (b), the first connector is connected to at least one of the second connectors to do at least one test among the short-circuit test, the open-circuit test, and the impedance test in step (c).

8. The method of claim 7, wherein, after step (d) is completed, step (b) to step (d) are repeatedly taken for a predetermined number of times before taking step (e).

9. The method of claim 8, wherein when step (b) is taken again, the first connector is connected to one of the second connectors which is different from the second connector connected in the previously taken step (b), which makes the test done in the following step (c) different from the test done in the previously taken step (c).

10. The method of claim 1, further comprising the step of:
(g) electrically disconnecting the conducting wire set and the probe module, and going through step (b) to step (d) again;
wherein step (f) is followed by step (g).
